(19) United States
(12) Patent Application Publication
(10) Pub. No.: US 2005/0283558 A1
(43) Pub. Date: Dec. 22, 2005

(54) Kiosk technology kit

(75) Inventor: Donald Wilson McDonald, Fife, SCT (GB)

Correspondence Address: KIRKPATRICK & LOCKHART NICHOLSON GRAHAM LLP;(FORMERLY KIRKPATRICK & LOCKHART LLP), 75 STATE STREET, BOSTON, MA, 02109-1808, US

(73) Assignee: Incorporated Technologies (Holdings) Limited, Clackmannanshire, SCT (GB)

(21) Appl. No.: 10/502,138

(22) PCT Filed: Jan. 20, 2003
(86) PCT No.: PCT/GB03/00204

§ 371 Date: Apr. 25, 2005

(30) Foreign Application Priority Data
Jan. 19, 2002 (GB) 0201223.5
Aug. 28, 2002 (GB) 0219913.1

(51) Int. Cl. H05K 7/10

(52) U.S. Cl. 710/301

(57) ABSTRACT

A control module (10) and socket server architecture that occupies one expansion slot on a PC motherboard providing several functions and ports needed for embedding a motherboard in a kiosk application environment. The control module includes a motherboard bus connector (11), a motherboard bus to serial port bridge module (12), at least one serial port connector (13) and a processor module (16).

This invention relates to computer systems, in particular, interfacing personal computers (PCs) to peripherals in a multi-media kiosk applications.

In an embedded environment such as a kiosk, a PC needs to be configured and supported with additional hardware to provide system reliability and robustness and multiple device interfaces.

In the prior art systems are known for embedding standard PC hardware within a kiosk application. Such a system is provided by Coynet UK Limited that uses hardware containing an embedded processor on a control circuit board programmed to influence the PC in a kiosk application. During initialisation of the PC, or if the PC control program is not in operation, the processor automatically detects potential vulnerability in the system and automatically takes steps to prevent use of this system until it is once more stable and secure.

A significant problem with this and other known prior art solutions to is the inefficient use of input/output (I/O) ports of the PC. I/O ports such as serial RS-232 ports are needed for communication with kiosk peripherals such as coin mechanisms, note readers, meters for counting, card readers and printers.

Even more ports, including RS-232 and motherboard expansion slots (e.g. PCI, Peripheral Component Interconnect) are needed for hardware used to monitor the health and security of the PC, for example, controlling the power supply and monitoring the software and hardware state of the PC. An uninterruptable power supply (UPS) is desirable for monitoring and control of power to the motherboard and this is typically monitored and controlled by the motherboard itself using an RS-232 port. A watchdog capability is useful to monitor the state of the PC and this typically requires a processor unit (e.g. a microcontroller) external to the motherboard connected to the motherboard via a RS-232 port and other connectors on the motherboard. In a kiosk system it is desirable to have digital Digital Input/Output (DIO), and this typically is achieved by using a PCI slot on the motherboard with a DIO card or by having an RS-232 port connection to a DIO device. An embedded system can be further improved with the ability to store customer specific data in non-volatile memory in order to provide security features, and this is typically achieved with the use of a PCI slot, an RS-232 port or a parallel port. Another desirable features is output to an amplifier and speaker which is typically done through a PCI slot with a sound card. Communication with other processor such as using the I²C (Inter-IC) bus would typically use another PCI slot the motherboard for a communications adapter card. The 1²C bus is a standard two-wire serial bus used in a variety of microcontroller-based embedded applications for control, diagnostics and power management. Yet another feature possible in an embedded system is monitoring of the state of batteries connected to the uninterruptable power supply, and this could be achieved using hardware connected to another port of the PC.

It can be seen that there are not enough ports on a standard PC motherboard to supply all of the connectivity to kiosks peripherals and for all of the desirable functions listed above. The conventional approach to this problem is to provide port expansion hardware, typically occupying a PCI slot with a bank of UARTs (Universal Asynchronous Receiver/Transmitters) controlled by a microcontroller. The problem with this approach is the cost and the complexity of software event handlers needed to control all of the peripherals attached via the bank of UARTs. It is not possible with this approach to use a standard plug and play architecture for added applications on the host PC because special event handler code needs to be written at the microcontroller level or a special abstraction layer and API (Application Programming Interface) needs to developed.

It would be advantageous to provide an architecture and a control module that fulfilled all of the desirable peripheral connection needs and all of the control functions for a PC in an embedded application such as a kiosk.

It is an object of the present invention to provide a control module and architecture that occupies one expansion slot on a PC motherboard while providing a plurality of functions and ports needed for embedding a motherboard in a kiosk application environment.

According to a first aspect of the present invention, there is provided a control module comprising:
a motherboard bus connector for communication with a motherboard;
a motherboard bus to serial port bridge module;
at least one serial port connector; and
a processor module.

Preferably the control module is adapted to provide at least one peripheral control port for said motherboard.

Preferably the processor module comprises a monitoring means for monitoring the state of said motherboard.

Typically, the monitoring means further monitors the state of software running on said motherboard.

Preferably the processor module has a battery power supply separate from the PC power supply.

Preferably processor module further comprises a power supply monitoring means for monitoring the state of a power supply supplying said motherboard.

According to a second aspect of the present invention, there is provided a system comprising a motherboard and the control module in accordance with the first aspect.

Preferably the system further comprises a socket server means for providing event handlers for at least one serial port corresponding to said at least one serial port connector and operating substantially in between the application layer and the operating system layer of the software executing on the motherboard.

More preferably, the system further comprises a socket server means for providing event handlers for said at least one peripheral control port and operating substantially in between the application layer and the operating system layer of the software executing on the motherboard.

Preferably, the system further comprises a battery, a power supply and a battery management circuit wherein an electrical connection between said battery and said power supply is diverted through said battery management circuit and said battery management circuit is controlled by said processor module.

In order to provide a better understanding of the present invention, an embodiment will now be described by way of example only and with reference to the accompanying figures in which:

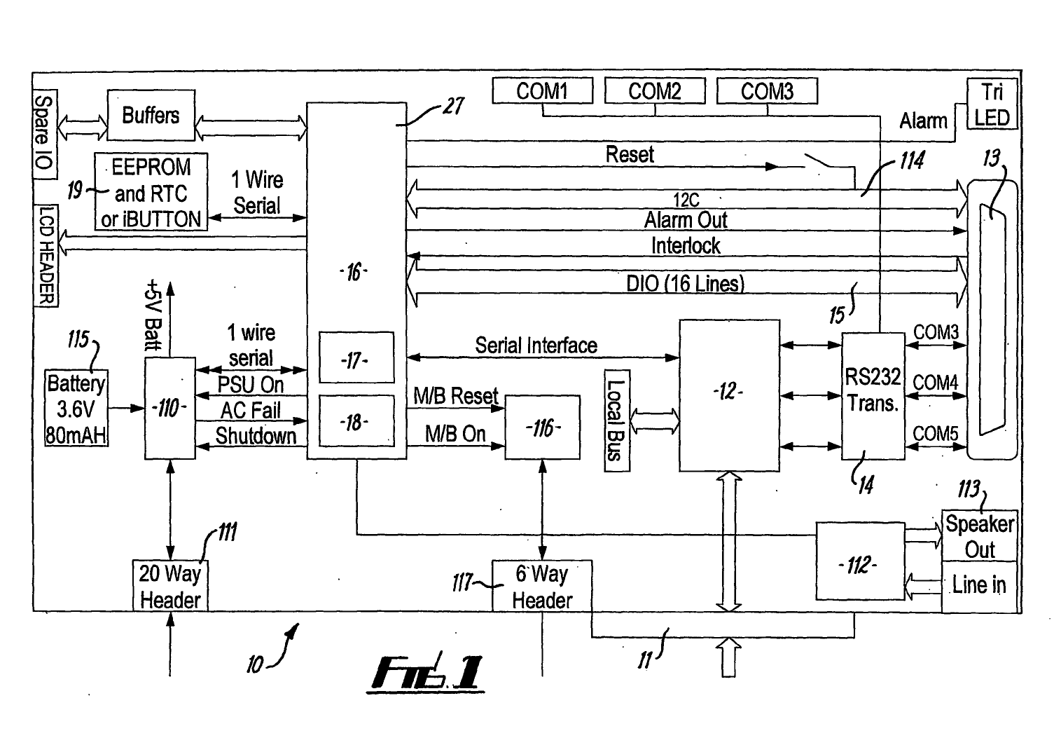

FIG. 1 illustrates in schematic form a control module in accordance with the present invention;

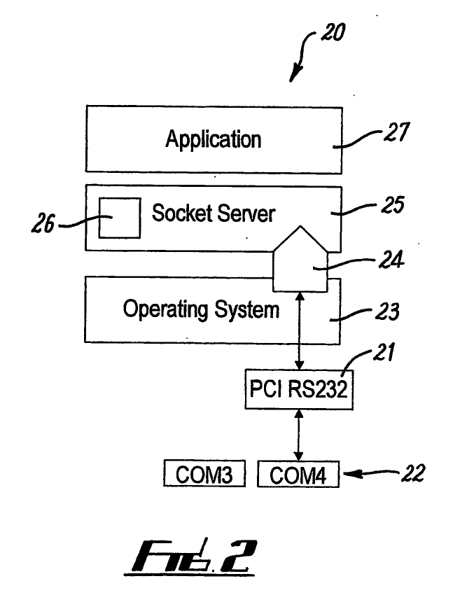

FIG. 2 illustrates in schematic form a software architecture in accordance with the present invention; and

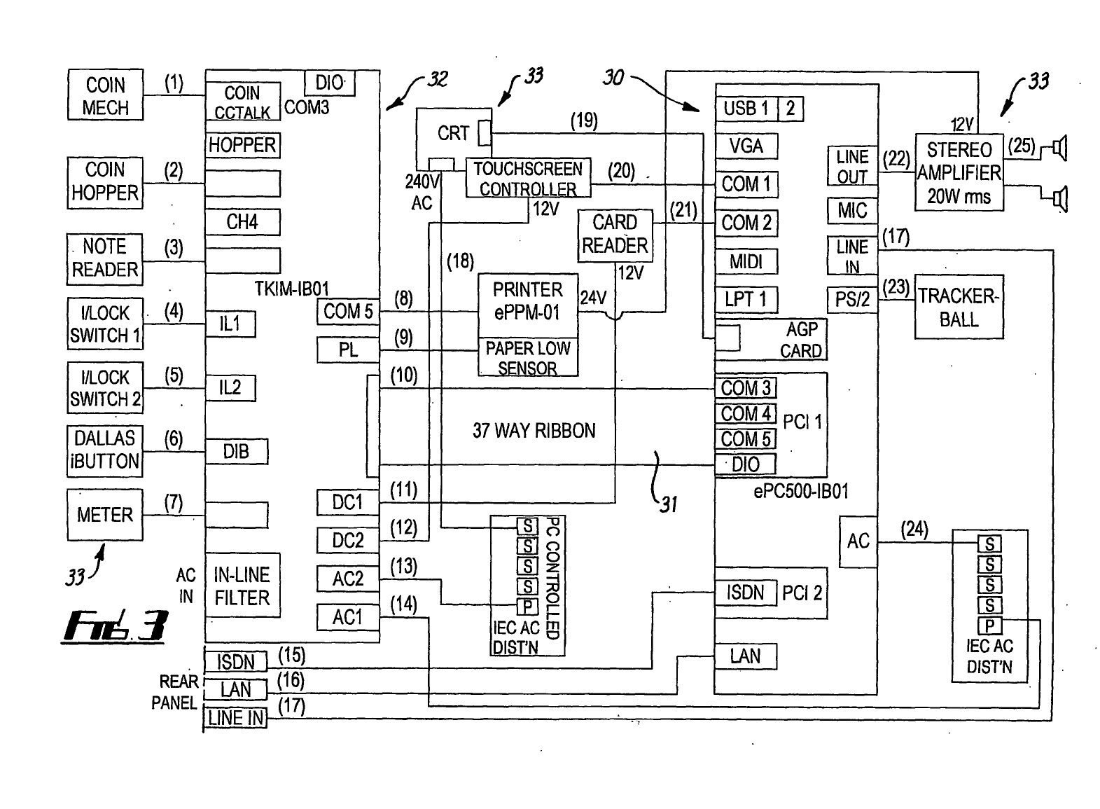

FIG. 3 illustrates in schematic form a system including a control module, a peripheral interface module and peripherals in accordance with the present invention.

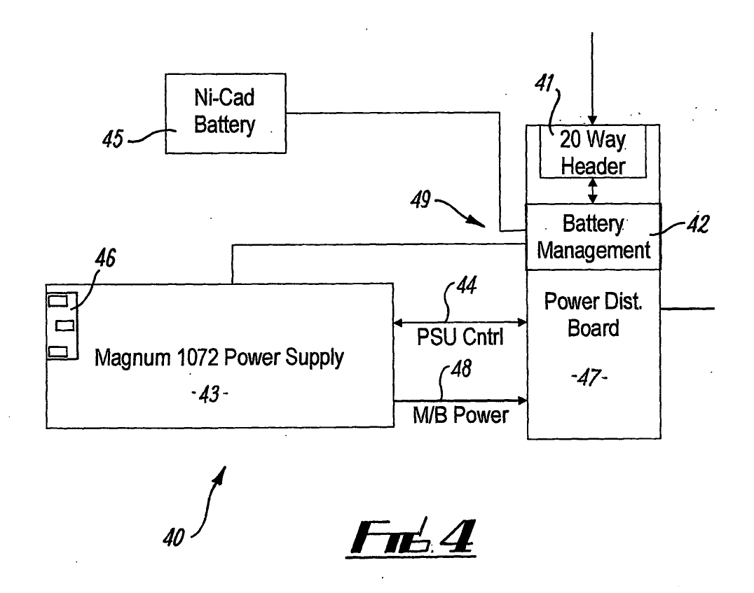

FIG. 4 illustrates in schematic form a power supply system in accordance with the present invention.

The invention is a card for connecting to a PC motherboard that functions to provide serial port expansion, digital I/O port (DIO) expansion and control functions for a PC in an embedded environment.

With reference to FIG. 1, the control module 10 is shown comprising a PCI connector 11, a PCI/RS-232 bridge chip 12 comprising four UARTs with output to a single multifunction connector 13 that includes three RS-232 ports 14 and two eight-bit DIO ports 15.

One RS-232 port from the bridge chip is connected to a processor module which is a microcontroller unit 16 that includes FLASH EEPROM memory 17 and boot loader ROM 18.

A Dallas iButton 19 from Dallas Semiconductor Corp. is provided for measuring temperature, providing further non-volatile memory (EEPROM), a real time clock and a unique serial number. The serial number is used for provision of security features, including software licence verification, thus acting as a ‘dongle’.

A power supply controller circuit 110 and connection 111 to the host motherboard's power supply unit is provided.

The microcontroller has its own back-up battery supply 115. An amplifier driver 112 for a speaker 113 and an I²C Bus interface 114 are also provided.

A motherboard interface 116 has a connector 117 for a cable to the motherboard reset and power on pins.

The microcontroller performs a number of key tasks and communicates with the host motherboard via the PCI slot. The full utilisation of the microcontroller requires installation of a socket server layer (described below with reference to FIG. 2) and a power control API on the host system.

The microcontroller provides management of the power system including the UPS and provides automatic shutdown of the system after a preset period of AC (alternating current) power loss. This is set to 3 minutes normally. In addition, some motherboard/operating system combinations can behave differently with respect to AC power loss and restart conditions. The microcontroller is programmed to automatically restart the system after power restoration and deal with any issues related to ACPM/BIOS (Advanced Configuration and Power Management/Basic Input/Output System).

If the host system hangs, there may be now no way to recover the system other than a full hardware reboot. The microcontroller can detect when the system hangs and automatically reboot. This can be programmed to cycle a number of times to try to recover the system. Reboot status is held within the microcontroller or iButton EEPROM.

The microcontroller or iButton EEPROM stores factory set-up data to aid situations where remote management is being used or for a quick status inspection in the field.

A 2×16 character LCD (Liquid Crystal Display) can be fitted to the control module to display system information. Factory device identity and local error codes can be displayed to provide assistance in diagnosing field problems.

The microcontroller is connected to the multifunction connector to provide a number of DIO ports for control applications. The DIO control lines are configured as inputs and outputs for system interfacing and control. All lines are fully buffered to TTL (Transistor-Transistor Logic) (5V) level. Examples of input signals are alarm state, paper low and interlocks. Examples of output signals are coin light and alarm reset. All output control lines are taken via a buffer and can sink/source 200 mA. A suitable external buffer device would be required to control larger currents.

With reference to FIG. 2 a software architecture 20 according to the present invention is shown schematically. A serial port driver 21 connects to serial ports 22. The operating system layer 23 contains sockets 24, which are interfaced via a software protocol to a socket server layer 25. The serial event handlers are a module 26 in the socket server layer. This provides an advantage over the prior art where serial event handlers are written in the firmware of a microcontroller unit in a serial port expansion module along with several costly UARTS. Finally, the application layer 27 is on top of the socket server layer.

In order to provide system integrators with a simple means of controlling peripherals, the socket server layer is provided as a run-time device manager based on a Windows™ sockets interface. An additional ActiveX™ component is also provided which, when combined with the socket server layer allows device control directly from HTML (HyperText Markup Language) and Java™ script. This considerably reduces the complexity of application development, allowing simple scripting to be used to control all devices.

With reference to FIG. 3 there is a PC 30 containing a controller module according to the present invention connected by a ribbon cable 31 (from the connector 13 of FIG. 1) to a peripheral interface module 32. This Figure demonstrates how the controller module can be used to embed a PC in a kiosk application. A large number of peripherals 33 are connected to the PC using its own ports, the ports of the controller module and through the connectors of the peripheral interface module.

The motherboard is a standard micro-ATX (Advanced Technology extended) form factor PC mainboard. Compared to standard ATX, it enables smaller, cost-reduced system designs. For example, the mainboard square area is reduced to approx. 92 square inches. It typically contains integrated graphics and audio, 2 DIMMs (Dual In line Memory Modules) and a maximum of 3 PCI slots. With reference to FIG. 4 there is a power supply 40 for embedding within the kiosk environment. The control module contains a connection 41 to a battery management circuit 42. The UPS 43 is a BiUPS® (Built-In UPS) from Magnum Power Solutions Limited, which has output control signals 44, a NiCd back-up battery 45 and an AC (alternating current) input 46. It provides the host computer system power distribution board 47 with embedded un-interruptible protection of the UPS power output 48. It occupies the same mechanical outline as an internal switched-mode power supply.

The degree of protection depends on the capacity of the back-up battery. The standard BiUPS system has two states for the charging of the back-up battery: fast and trickle charge. The problem with this is that the NiCd battery is not optimally conditioned. In this embodiment, the system is improved by diverting the electrical connection 49 of the NiCd battery to the BiUPS power supply through a battery management circuit that is controlled by the microcontroller. This battery management function, combined with the other power supply control signals between the power supply and the microcontroller, allow the monitoring and control of the optimum charging conditions of the back-up battery.

Further modifications and improvements may be added without departing from the scope of the invention herein described

1. A control module comprising:
a motherboard bus connector for communication with a motherboard;
a motherboard bus to serial port bridge module;
at least one serial port connector; and
a processor module.

2. The control module of claim 1 adapted to provide at least one peripheral control port for said motherboard.

3. The control module of claim 1 wherein the processor module comprises a monitoring means for monitoring the state of said motherboard.

4. The control module of claim 3 wherein the monitoring means further monitors the state of software running on said motherboard.

5. The control module of claim 1 wherein the processor module has a battery power supply separate from the PC power supply.

6. The control module of claim 1 wherein the processor module further comprises a power supply monitoring means for monitoring the state of a power supply supplying said motherboard.

7. A system comprising a motherboard and the control module of claim 1.

8. The system of claim 7 further comprising a socket server means for providing event handlers for at least one serial port corresponding to said at least one serial port connector and operating substantially in between the application layer and the operating system layer of the software executing on the motherboard.

9. The system of claim 7 further comprising a socket server means for providing event handlers for said at least one peripheral control port and operating substantially in between the application layer and the operating system layer of the software executing on the motherboard.

10. The system of claim 7 further comprising a battery, a power supply and a battery management circuit wherein an electrical connection between said battery and said power supply is diverted through said battery management circuit and said battery management circuit is controlled by said processor module.
